(19) United States
(12) Patent Application Publication
(10) Pub. No.: US 2025/0390016 A1
(43) Pub. Date: Dec. 25, 2025

(54) DATA VERIFICATION METHOD OF PHOTOMASK PRODUCT, COMPUTER-READABLE RECORDING MEDIA AND ELECTRONIC APPARATUS

(71) Applicant: Winbond Electronics Corp., Taichung City (TW)

(72) Inventor: Chih-Wei Liao, Hsinchu County (TW)

(73) Assignee: Winbond Electronics Corp., Taichung City (TW)

(21) Appl. No.: 19/215,343

(22) Filed: May 22, 2025

(30) Foreign Application Priority Data
Jun. 25, 2024 (TW) 113123626

(51) Int. Cl. G03F 1/84

(52) U.S. Cl. CPC G03F 1/84

(57) ABSTRACT

A data verification method of a photomask product is disclosed. The data verification method includes: measuring first characterization data of a first photomask product; predicting second characterization data of the first photomask product using a data verification model based on the first characterization data and reference characterization data; updating the data verification model of the first photomask product according to the first characterization data and the second characterization data; and updating the data verification model in a database for future photomask product predictions.

### CROSS-REFERENCE TO RELATED APPLICATION

This application claims the priority benefit of Taiwan application serial no. 113123626, filed on Jun. 25, 2024. The entirety of the above-mentioned patent application is hereby incorporated by reference herein and made a part of this specification.

### BACKGROUND

### Technical Field

This disclosure relates to a data verification method, a computer-readable recording media, and an electronic apparatus, in particular to a data verification method of a photomask product, a computer-readable recording media, and an electronic apparatus.

### Description of Related Art

Generally speaking, it is necessary to verify data of the photomask products after they are finished to make sure whether the finished photomask products meet the characteristics specified in the product specification. In the case of a photomask product of flash memory, for example, multiple combinations of characteristic parameters must be measured for the photomask product of flash memory during the data verification process. This would take too much time to verify the photomask product.

### SUMMARY

The disclosure provides a data verification method of a photomask product, a computer-readable recording media, and an electronic apparatus, capable of significantly reducing a time for data verification of the photomask product.

An embodiment of the disclosure provides a data verification method of a photomask product, including the following. First characterization data of a first photomask product is measured. Based on the first characterization data and reference characterization data, second characterization data of the first photomask product is predicted using a data verification model. According to the first characterization data and the second characterization data, the data verification model of the first photomask product is updated. The data verification model is updated in a database for future photomask product predictions.

A computer-readable recording media according to an embodiment of the disclosure includes a computer program. The computer program enables a computer to execute the data verification method of the photomask product after executing the computer program.

An electronic apparatus according to an embodiment of the disclosure includes a processor and a storage element. The storage element stores a computer program. The computer program enables the processor to execute the data verification method of the photomask product after executing the computer program.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic block diagram of an electronic apparatus according to an embodiment of the disclosure.

FIG. 2 is a schematic block diagram of a photomask product measured by the electronic apparatus according to the embodiment of FIG. 1 controlling a measuring machine.

FIG. 3 illustrates a data verification method of a photomask product according to an embodiment of the disclosure.

FIG. 4 illustrates a data verification method of a photomask product according to another embodiment of the disclosure.

### DESCRIPTION OF THE EMBODIMENTS

Embodiments of the disclosure provides a data verification method of a photomask product, whereby a data validation model may be used to predict characterization data of a new photomask product (a first photomask product) based on characterization data of an old photomask product (a second photomask product) to significantly reduce the time required to perform data validation of the new photomask product. In one embodiment, the data verification model is, for example, an artificial intelligence (AI) model.

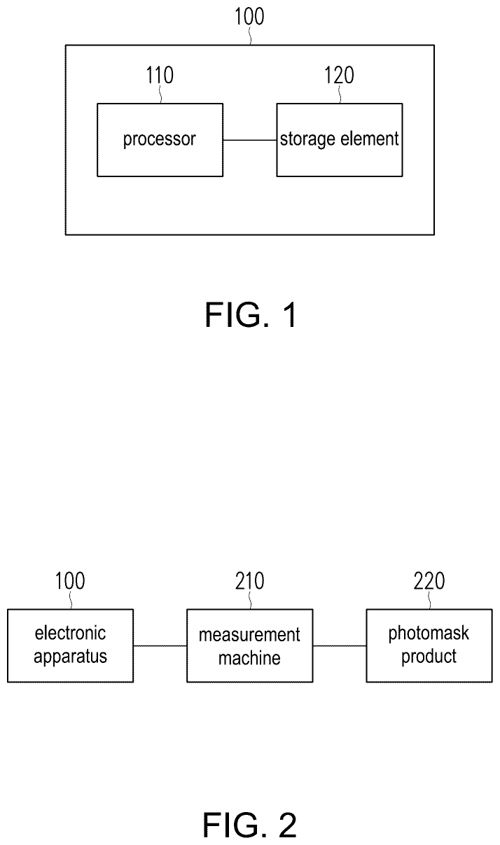

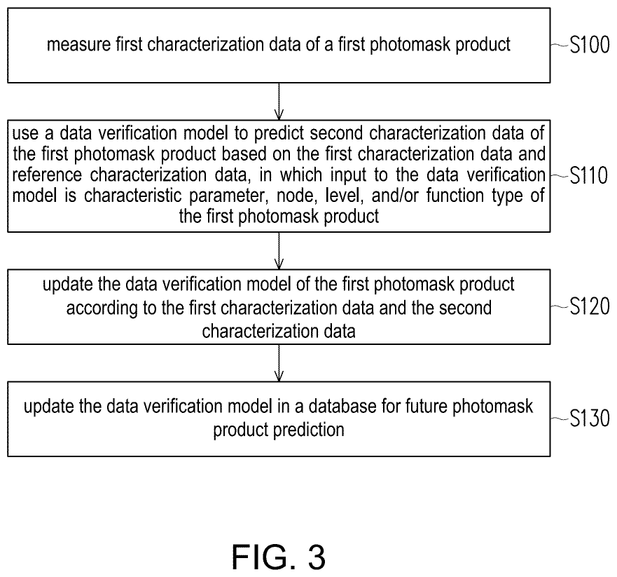

FIG. 1 is a schematic block diagram of an electronic apparatus according to an embodiment of the disclosure. FIG. 2 is a schematic block diagram of a photomask product measured by the electronic apparatus according to the embodiment of FIG. 1 controlling a measuring machine. FIG. 3 illustrates a data verification method of a photomask product according to an embodiment of the disclosure. Referring to FIG. 1 and FIG. 3, an electronic apparatus 100 includes a processor 110 and a storage element 120. In one embodiment, the electronic apparatus 100 is, for example, a computer, and the storage element 120 is, for example, a computer-readable recording media, including a computer program. After executing the computer program, the electronic apparatus 100 may execute the data verification method of the photomask product in FIG. 3.

In step S100, the processor 110 may control a measurement machine 210 to measure first characterization data of a first photomask product 220 under set conditions of a first characteristic parameter combination. The characterization data includes, but is not limited to, AC electrical characteristics and DC electrical characteristics noted in the product datasheet. The first photomask product is the new photomask product.

The measuring machine 210 measures the first characterization data of the first photomask product 220 under the set conditions of the first characteristic parameter combination. The first characteristic parameter combination is, for example, a combination selected from different voltage parameters and different temperature parameters. For example, the first characteristic parameter combination may be a combination selecting any number from voltage parameters 1.6 Volts (V), 1.65V, 1.7V, 1.8V, 1.95V, 2.05V, and selecting any number from temperature parameter −45 Celsius (° C.), 25° C., 90° C., 110° C., 130° C. For example, the first characteristic parameter combination is a combination of voltage parameters 1.6V, 1.8V, 1.95V and temperature parameters −45° C., 25° C., 90° C., 110° C., 130° C. That is, the first characteristic parameter combination is a part selected from the characteristic parameter combination (a third characteristic parameter combination). The voltage parameters and the temperature parameters are only used for illustration and are not intended to limit the disclosure.

Thus, in step S100, the measuring machine 210 measures the first characterization data of the first photomask product 220 when an operating voltage of 1.6V, 1.8V, 1.95V is applied to the first photomask product 220 at temperatures of −45° C., 25° C., 90° C., 110° C., 130° C., respectively.

Next, in step S110, the processor 110 uses the data verification model to predict second characterization data of the first photomask product 220 based on the first characterization data and reference characterization data. Input to the data verification model is a characteristic parameter, a node, a level, and/or a function type of the first photomask product 220. In this embodiment, the characteristic parameter may be product category, photomask, instruction, voltage, and/or temperature. The data verification model is, for example, an AI model, and the node is neuron-like analysis parameter constructed in a neural network in the AI model. The level is a group analysis parameter constructed in a random forest in the AI model. The function type is the use of different modules (neural network and/or random forest) in the AI model for analysis.

Specifically, the processor 110 uses the data verification model to predict the second characterization data of the first photomask product 220 under set conditions of a second characteristic parameter combination. For example, the processor 110 may use the data verification model to predict the second characterization data of the first photomask product 220 when an operating voltage of 1.65V, 1.7V, 2.05V is applied to the first photomask product 220 at temperatures of −45° C., 25° C., 90° C., 110° C., 130° C., respectively, based on the first characterization data and the reference characterization data. That is, the second characteristic parameter combination is another part selected from the third characteristic parameter combination. In addition, the processor 110 uses AI technology to predict the second characterization data of the first photomask product 220, for example. AI technology includes but is not limited to machine learning and deep learning.

In this embodiment, the reference characterization data is, for example, known characterization data of the second photomask product, and may be stored in the storage element 120 or cloud database in advance. The second photomask product is the old photomask product, and a first photomask and a second photomask are different.

In this embodiment, the reference characterization data is, for example, characterization data measured by the measuring machine 210 when an operating voltage of 1.6V, 1.65V, 1.7V, 1.8V, 1.95V, 2.05V is applied to the second photomask product (the old photomask product) at temperatures of −45° C., 25° C., 90° C., 110° C., and 130° C. The temperature −45° C., 25° C., 90° C., 110° C., 130° C. and the operating voltage 1.6V, 1.65V, 1.7V, 1.8V, 1.95V, 2.05V are the third characteristic parameter combination.

Thus, in this embodiment, the first characteristic parameter combination, the second characteristic parameter combination, and the third characteristic parameter combination are parameter combinations including multiple voltages and multiple temperatures. The first characteristic parameter combination is selected from a part of the third characteristic parameter combination, and the second characteristic parameter combination is selected from another part of the third characteristic parameter combination. The first characterization data, the second characterization data, and the reference characterization data are characterization data related to the first characteristic parameter combination, the second characteristic parameter combination, and the third characteristic parameter combination respectively.

In addition, since the first characteristic parameter combination is selected from a part of the third characteristic parameter combination, amount of the first characterization data measured based on the first characteristic parameter combination may be less than amount of the reference characterization data. On the other hand, since the second characteristic parameter combination is selected from another part of the third characteristic parameter combination, amount of the predicted second characterization data is also less than amount of the reference characterization data. A sum of the amount of the first characterization data and the second characterization data is equal to the amount of the reference characterization data.

Next, in step S120, the processor 110 updates the data verification model of the first photomask product 220 according to the first characterization data and the second characterization data. In step S130, the data verification model is updated in a database for future photomask product predictions. A method of updating the model and verification data may be adequately taught, recommended, and practiced by general knowledge in the technical fields.

In conclusion, in this embodiment, for the first photomask product 220 produced using a new photomask, since the processor 110 only needs to measure the first characterization data corresponding to a part of the characteristic parameter combination, and the second characterization data corresponding to another part of the characteristic parameter combination may be predicted by the data verification model based on the first characterization data and the reference characterization data of the second photomask product (the old photomask product), the time for performing the data verification on the first photomask product 220 may be greatly reduced.

In one embodiment, the processor 110 is, for example, a central processing unit (CPU), or other programmable general-purpose or special-purpose micro control unit (MCU), microprocessor, digital signal processor (DSP), programmable controller, application specific integrated circuit (ASIC), graphics processing unit (GPU), image signal processor (ISP), image processing unit (IPU), arithmetic logic unit (ALU), complex programmable logic device (CPLD), field programmable gate array (FPGA), or other similar elements or a combination of the above elements.

In one embodiment, the storage element 120 is used to store various software, data, and various program codes required when the electronic apparatus 100 is running. The storage element 120 is, for example, any type of fixed or removable random access memory (RAM), read-only memory (ROM), or flash memory, hard disk drive (HDD), solid state drive (SSD), or similar elements or a combination of the above elements, used to store multiple modules or various application programs that can be executed by the processor 110. In one embodiment, the storage element 120 may further include a database.

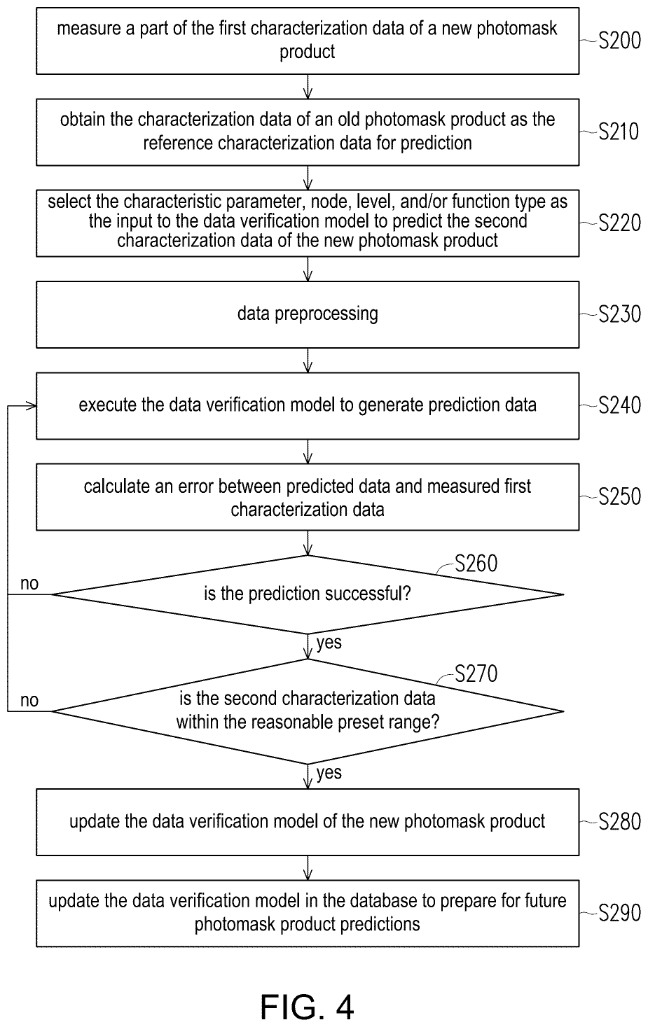

FIG. 4 illustrates a data verification method of a photomask product according to another embodiment of the disclosure. Referring to FIG. 1, FIG. 2, and FIG. 4, in step S200, the processor 110 controls the measuring machine 210 to measure a part of the characterization data (the first characterization data) of the new photomask product. In step S210, the processor 110 obtains the characterization data of the old photomask product as the reference characterization data for prediction. In step S220, the processor 110 uses the data verification model to predict the second characterization data of the first photomask product 220 based on the first characterization data and the reference characterization data. Input to the data verification model is a characteristic parameter, a node, a level, and/or a function type of the first photomask product 220. Thus, in step S220, the processor 110 selects the characteristic parameter, the node, the level, and/or the function type of the first photomask product 220 as the input to the data verification model.

Next, in step S230, the processor 110 performs data preprocessing on the reference characterization data of the old photomask product and the part of the characterization data of the new photomask product. In step S240, the processor 110 executes the data verification model (such as a neural network) to generate prediction data. The prediction data includes unmeasured data (the second characterization data) and actual measured data (the first characterization data). That is, in step S240, in addition to predicting the second characterization data of the new photomask product based on the first characterization data and reference characterization data, the processor 110 also predicts the first characterization data of the new photomask product based on the first characterization data and the reference characterization data.

In step S250, the processor 110 calculates an error between predicted first characterization data and measured first characterization data. Next, in step S260, the processor 110 determines whether the second characterization data of the new photomask product is successfully predicted based on the error. For example, if the error between 90% of the predicted first characterization data and the measured first characterization data is less than a reference value, the processor 110 determines that the prediction of the first characterization data is successful, indicating that at the same time, the prediction of the second characteristic data is also successful.

In step S260, if the prediction of the second characterization data is successful, the processor 110 executes step S270. In step S270, the processor 110 performs a small amount of verification on the second characterization data to determine whether the second characterization data is within a reasonable preset range. For example, the predicted second characterization data is randomly selected for verification to confirm whether the second characterization data is reasonable. On the other hand, in step S260, if the prediction of the second characterization data is unsuccessful, the processor 110 returns to step S240 and executes the data verification model again to generate prediction data.

In step S280, if the second characterization data is within the preset range, the processor 110 executes step S280. In step S280, the processor 110 updates the data verification model of the new photomask product. Next, in step S290, the data verification model is updated in the database to prepare for future photomask product predictions. On the other hand, in step S270, if the second characterization data is not within the reasonable preset range, the processor 110 returns to step S240 and executes the data verification model again to generate prediction data.

In addition, the data verification method of this embodiment may be adequately taught, recommended, and practiced from the description of the embodiments in FIG. 1 to FIG. 3, and therefore will not be repeated in the following.

To sum up, in the embodiment of the disclosure, for the new photomask product, since the processor only needs to measure a part of the characterization data, and the other part of the characterization data may be predicted by the data verification model based on the measured characterization data and the characterization data of the old photomask product, the time for data verification of the new photomask product may be greatly reduced. In addition, the data verification method provided by the embodiment of the disclosure may verify whether the photomask product complies with preset product specifications. If it is verified that the photomask product does not meet the preset product specifications, the design department may adjust and design a new circuit for the product accordingly, improve the product characteristics, and perfect the product performance.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A data verification method of a photomask product, comprising:
measuring first characterization data of a first photomask product;
based on the first characterization data and reference characterization data, predicting second characterization data of the first photomask product using a data verification model, wherein input to the data verification model is a characteristic parameter, a node, a level, and/or a function type of the first photomask product;
according to the first characterization data and the second characterization data, updating the data verification model of the first photomask product; and
updating the data verification model in a database for future photomask product predictions.

2. The data verification method of the photomask product according to claim 1, wherein an amount of the first characterization data is less than an amount of the reference characterization data.

3. The data verification method of the photomask product according to claim 2, wherein a sum of an amount of the first characterization data and the second characterization data is equal to the amount of the reference characterization data.

4. The data verification method of the photomask product according to claim 1, wherein the reference characterization data is known characterization data of the second photomask product.

5. The data verification method of the photomask product according to claim 1, wherein the first characterization data, the second characterization data, and the reference characterization data are characterization data related to a first characteristic parameter combination, a second characteristic parameter combination, and a third characteristic parameter combination respectively, wherein the first characteristic parameter combination is selected from a part of the third characteristic parameter combination, and the second characteristic parameter combination is selected from another part of the third characteristic parameter combination.

6. The data verification method of the photomask product according to claim 5, wherein the first characteristic parameter combination, the second characteristic parameter combination, and the third characteristic parameter combination are parameter combinations comprising a plurality of voltages and a plurality of temperatures.

7. The data verification method of the photomask product according to claim 1, comprising:
based on the first characterization data and the reference characterization data, predicting the first characterization data of the first photomask product;
calculating an error between the first characterization data obtained by prediction and the first characterization data obtained by measurement; and
determining whether the second characterization data of the first photomask product is successfully predicted according to the error.

8. The data verification method of the photomask product according to claim 7, wherein
if the second characterization data of the first photomask product is successfully predicted, the data verification method further comprises performing a small amount of verification on the second characterization data to determine whether the second characterization data is within a preset range; and
if the prediction of the second characterization data of the first photomask product is unsuccessful, the data verification method performs predicting the second characterization data of the first photomask product again.

9. The data verification method of the photomask product according to claim 8, wherein
if the second characterization data is within the preset range, the data verification method performs updating the data verification model of the first photomask product; and
if the second characterization data is not within the preset range, the data verification method performs predicting the second characterization data of the first photomask product again.

10. A computer-readable recording media, comprising a computer program enabling a computer to execute a data verification method of a photomask product after executing the computer program, wherein the data verification method of the photomask product comprises:
measuring first characterization data of a first photomask product;
based on the first characterization data and reference characterization data, predicting second characterization data of the first photomask product using a data verification model, wherein input to the data verification model is a characteristic parameter, a node, a level, and/or a function type of the first photomask product;
according to the first characterization data and the second characterization data, updating the data verification model of the first photomask product; and
updating the data verification model in a database for future photomask product predictions.

11. The computer-readable recording media according to claim 10, wherein an amount of the first characterization data is less than an amount of the reference characterization data.

12. The computer-readable recording media according to claim 11, wherein a sum of an amount of the first characterization data and the second characterization data is equal to the amount of the reference characterization data.

13. The computer-readable recording media according to claim 10, wherein the reference characterization data is known characterization data of the second photomask product.

14. The computer-readable recording media according to claim 10, wherein the first characterization data, the second characterization data, and the reference characterization data are characterization data related to a first characteristic parameter combination, a second characteristic parameter combination, and a third characteristic parameter combination respectively, wherein the first characteristic parameter combination is selected from a part of the third characteristic parameter combination, and the second characteristic parameter combination is selected from another part of the third characteristic parameter combination.

15. The computer-readable recording media according to claim 14, wherein the first characteristic parameter combination, the second characteristic parameter combination, and the third characteristic parameter combination are parameter combinations comprising a plurality of voltages and a plurality of temperatures.

16. The computer-readable recording media according to claim 10, wherein the data verification method of the photomask product further comprises:
based on the first characterization data and the reference characterization data, predicting the first characterization data of the first photomask product;
calculating an error between the first characterization data obtained by prediction and the first characterization data obtained by measurement; and
determining whether the second characterization data of the first photomask product is successfully predicted according to the error.

17. An electronic apparatus, comprising a processor and a storage element, wherein the storage element stores a computer program enabling the processor to execute a data verification method of a photomask product after executing the computer program, wherein the data verification method of the photomask product comprises:
measuring first characterization data of a first photomask product;
based on the first characterization data and reference characterization data, predicting second characterization data of the first photomask product using a data verification model, wherein input to the data verification model is a characteristic parameter, a node, a level, and/or a function type of the first photomask product;
according to the first characterization data and the second characterization data, updating the data verification model of the first photomask product; and
updating the data verification model in a database for future photomask product predictions.

18. The electronic apparatus according to claim 17, wherein the data verification method of the photomask product further comprises:
based on the first characterization data and the reference characterization data, predicting the first characterization data of the first photomask product;
calculating an error between the first characterization data obtained by prediction and the first characterization data obtained by measurement; and
determining whether the second characterization data of the first photomask product is successfully predicted according to the error.

19. The electronic apparatus according to claim 18, wherein
if the second characterization data of the first photomask product is successfully predicted, the data verification method further comprises performing a small amount of verification on the second characterization data to determine whether the second characterization data is within a preset range;
and if the prediction of the second characterization data of the first photomask product is unsuccessful, the data verification method performs predicting the second characterization data of the first photomask product again.

20. The electronic apparatus according to claim 19, wherein
if the second characterization data is within the preset range, the data verification method performs updating the data verification model of the first photomask product; and
if the second characterization data is not within the preset range, the data verification method performs predicting the second characterization data of the first photomask product again.
